(19) United States
(12) Patent Application Publication
(10) Pub. No.: US 2025/0379115 A1
(43) Pub. Date: Dec. 11, 2025

(54) ELECTRONIC DEVICE AND A METHOD FOR FORMING THE SAME

(71) Applicant: STATS ChipPAC Pte. Ltd., Singapore (SG)

(72) Inventors: YongHyuk JEONG, Incheon (KR); DaAe LEE, Incheon (KR); EunByeol SON, Gyeong-gi (KR)

(21) Appl. No.: 19/230,037

(22) Filed: Jun. 5, 2025

(30) Foreign Application Priority Data
Jun. 7, 2024 (CN) 202410740203.8

(51) Int. Cl. H01L 23/367; H01L 21/48; H01L 21/56; H01L 23/31; H01L 23/498; H01L 25/00; H01L 25/065; H10B 80/00

(52) U.S. Cl. CPC H01L 23/3675; H01L 21/4853; H01L 21/4882; H01L 21/565; H01L 23/3121; H01L 23/49833; H01L 25/0652; H01L 25/50; H10B 80/00

(57) ABSTRACT

An electronic device is provided, wherein the electronic device comprises: a package substrate; two interposers disposed on the package substrate; an electronic component mounted on the two interposers to be electrically coupled to the package substrate via the two interposers; a mold cap formed on the package substrate to encapsulate the two interposers and expose the electronic component, wherein the mold cap comprises two sets of interconnects extending therethrough and each being electrically coupled to one of the interposers; two semiconductor dice mounted on the mold cap and the electronic component to form a gap between the two semiconductor dice and above the electronic component, wherein each of the two semiconductor dice is electrically coupled to one of the two interposers via one set of the two sets of interconnects; and a heat spreader attached on and thermally coupled to the two semiconductor dice and the electronic component.

### TECHNICAL FIELD

The present application generally relates to semiconductor technology, and more particularly, to an electronic device and a method for forming an electronic device.

### BACKGROUND OF THE INVENTION

The semiconductor industry is constantly faced with complex integration challenges as consumers want their electronics to be smaller, faster and higher performance with more and more functionalities packed into a single device. In recent years, System on a Chip (SOC) modules are widely used in integrated electronic devices. Typically, in some high-performance devices, the SOC modules can be packaged in conjunction with various semiconductor modules, for example, memory dice, to provide better performance and multi-functionality.

Therefore, a need exists for an electronic device incorporating various electronic modules with an improved integration level and heat dissipation.

### SUMMARY OF THE INVENTION

An objective of the present application is to provide an electronic device incorporating various electronic modules with an improved integration level and heat dissipation.

According to an aspect of the present application, an electronic device is provided. The electronic device comprises: a package substrate; two interposers disposed on the package substrate; an electronic component mounted on the two interposers to be electrically coupled to the package substrate via the two interposers; a mold cap formed on the package substrate to encapsulate the two interposers and expose the electronic component, wherein the mold cap comprises two sets of interconnects extending therethrough and each being electrically coupled to one of the interposers; two semiconductor dice mounted on the mold cap and the electronic component to form a gap between the two semiconductor dice and above the electronic component, wherein each of the two semiconductor dice is electrically coupled to one of the two interposers via one set of the two sets of interconnects; and a heat spreader attached on and thermally coupled to the two semiconductor dice, wherein a portion of the heat spreader extends downward into the gap to be thermally coupled to the electronic component.

According to another aspect of the present application, a method for forming an electronic device is provided. The method comprises: providing a package substrate; disposing two interposers on the package substrate; mounting an electronic component on the two interposers; forming a mold cap on the package substrate to encapsulate the two interposers and expose the electronic component; forming two sets of interconnects through the mold cap to electrically couple each set of the two sets of interconnects to one of the two interposers; mounting two semiconductor dice on the mold cap and the electronic component to form a gap between the two semiconductor dice and above the electronic component, wherein each of the two semiconductor dice is electrically coupled to one of the two interposers via one set of the two sets of interconnects; and attaching a heat spreader on the two semiconductor dice to thermally couple the heat spreader to the two semiconductor dice, wherein a portion of the heat spreader extends downward into the gap to be thermally coupled to the electronic component.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1E illustrate an electronic device and various steps of a method for forming the electronic device according to a first embodiment of the present application.

FIGS. 2A to 2E illustrate an electronic device and various steps of a method for forming the electronic device according to a second embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, in some high-performance devices, the SOC modules can be packaged in conjunction with various semiconductor modules, for example, memory dice, to provide better performance and multi-functionality. Recently, 2.5D electronic packages are widely adopted for their reduced size compared with conventional 2D electronic packages. Typically, a 2.5D electronic package includes an interposer attached on a package substrate for mounting of a SOC module and a memory die thereon side by side, so as to electrically couple the SOC module to the memory die via the interposer. However, a package size and a heat dissipation capability of such 2.5D electronic package still need to be improved, so as to integrate more components in a single semiconductor device.

To address this issue, in some embodiments, a new electronic device is provided. The electronic device includes two semiconductor dice mounted on an electronic component, and each of the two semiconductor dice overlaps with a portion of the electronic component to form a gap between the two semiconductor dice. The electronic device also includes a heat spreader thermally coupled to the two semiconductor dice with a portion of the heat spreader extending downward into the corresponding gap, such that the heat spreader can be thermally coupled to the electronic component. As such, an integration level and heat dissipation of such electronic package may be improved, thereby achieving a better performance.

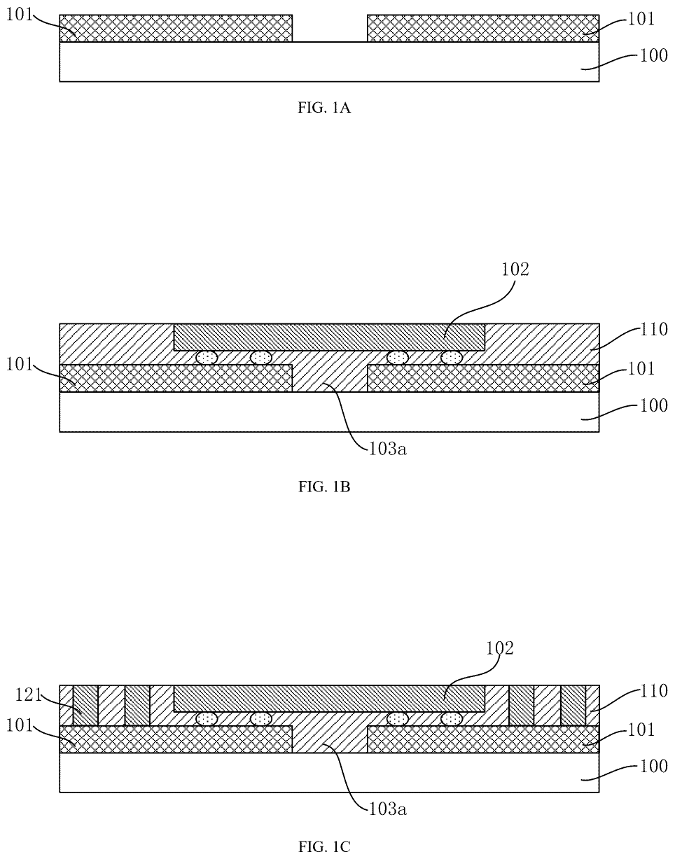

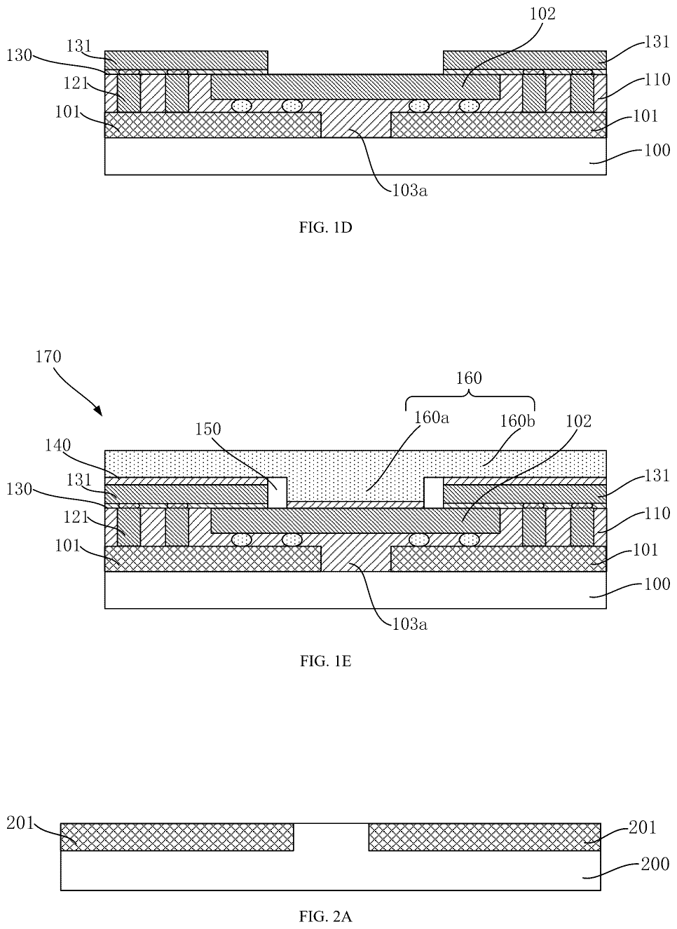

FIGS. 1A to 1E illustrate an electronic device and various steps of a method for forming the electronic device according to a first embodiment of the present application. The electronic device formed using the method may be shown in FIG. 1E.

As shown in FIG. 1A, a package substrate 100 is provided with embedded interconnect wires (not shown). The package substrate 100 includes a top surface and a bottom surface, which are opposite to each other. The top surface of the package substrate 100 may serve as a platform where electronic module(s) can be mounted. In some embodiments, the semiconductor package may be a double-sided mounted (DSM) package, and accordingly, the bottom surface may also serve as another platform where other electronic module(s) may be mounted or attached. Multiple sets of conductive pads (not shown) can be formed on the top surface and/or the bottom surface of the package substrate 100 for mounting the electronic module(s). It can be appreciated that the multiple sets of conductive pads may be exposed portions of the interconnect wires embedded within the package substrate 100. In some embodiments, the package substrate 100 may include a printed circuit board.

Next, two interposers 101 are disposed on the top surface of the package substrate 100. To be more specific, the two interposers 101 are juxtaposed on the top surface of the package substrate 100, and in some embodiments, top surfaces of the two interposers 101 are flush with each other to form a flat plane above the package substrate 100. As shown in FIG. 1A, the two interposers 101 may form a gap between them and above the package substrate 100. In some embodiments, the two interposers 101 may each provide electrical connections among various electronic modules mounted on the interposer 101 in a subsequent process, so as to shorten distances among various electronic modules. In some embodiments, each of the two interposers 101 may include at least one conductive wire (not shown) which is surrounded by an interposer base. The interposer base may include a dielectric material such as silicon dioxide or a semiconductor material such as silicon, or may include other dielectric materials such as epoxy resin or similar polymer or dielectric materials. Each of the conductive wire(s) may have a first conductive pad on one end and a second conductive pad on the other end, which are both exposed from the top surface of the interposer 101, with a main section that connects the two ends extending and embedded in the interposer base. In some embodiments, the number of the conductive wires included in each of the two interposers 101 may be two or more, depending on the number of pads of the electronic modules attached on the interposer 101 and requiring electrical connection with other components. Furthermore, each of the two interposers 101 may include additional connection structures to enable the interposer 101 to be electrically coupled to the interconnect wires within the package substrate 100 through additional electrical connections, for example, conductive pillars between the interposer 101 and the package substrate 100.

As shown in FIG. 1B, an electronic component 102 is mounted on the two interposers 101 via solder bumps, and is thus electronically coupled to the package substrate 100 via the two interposers 101. To be more specific, the electronic component 102 is mounted on at least a portion of a front surface of each of the two interposers 101, and thus disposed across the gap between the two interposers 101. In the embodiment shown in FIG. 1B, the electronic component 102 includes a system on a chip (SOC) device, which may be big in size. In some other embodiments, the electronic component 102 may include other electronic modules such as a central processing (CPU) module, a graphics processing (GPU) module or other pre-molded electronic packages. As mentioned above, in some embodiments, the two interposers 101 are flush with each other, and thus the electronic component 102 may be supported on the interposers 101 without a substantial tilt relative to the package substrate 100.

Next, a mold cap 110 is formed on the package substrate 100 to encapsulate the two interposers 101 and the electronic component 102 but expose a front surface of the electronic component 102. In some embodiments, the mold cap 110 is formed using a molding process such as an injection molding process, which covers respective top surfaces of the electronic component 102 and the two interposers 101 for encapsulation. To be more specific, a molding material may be applied on the package substrate 100, which fills in the gap between the two interposers 101 and covers the electronic component 102 and the two interposers 101. The molding material may then be heated and cured, thus forming the mold cap 110 with a protrusion 103a extending downward onto the package substrate 100 and between the two interposers 101. As such, the two interposers 101 and the electronic component 102 may be encapsulated by the mold cap 110 and fixed at certain positions on the package substrate 100. In some embodiments, the molding material includes epoxy, polyester resin, or any other suitable materials. In some other embodiments, the mold cap 110 may be formed using various other molding technologies, including a transfer molding process, a compression molding process or a film-assisted molding (FAM) process. Optionally, the interposers 101 and the electronic component 102 may be over-molded, with an excess portion of the molding material formed above the electronic component 102. In that case, a grinding process may be conducted to the mold cap 110, so as to remove the excess portion of the mold cap 110 above the electronic component 102 till exposure of the front surface of the electronic component 102.

Next, as shown in FIG. 1C, two sets of interconnects 121 are formed through the mold cap 110 and around the electronic component 102 at two opposite sides of the electronic component 102. The interconnects 121 can be electrically coupled to the two interposers 101. In this embodiment, each set of the two sets of interconnects 121 may include two or more conductive vias being mounted on one of the two interposers 101. To be more specific, a formation process of the conductive vias may include following steps. First, two sets of through holes are formed within the mold cap 110. Each set of the two sets of through holes are aligned with one of the two interposers 101 and may include two or more through holes each exposing a top surface of one of the two interposers 101. The through holes may be formed using laser ablation, or other techniques such as etching, milling, drilling, pinching or their combinations. Next, a conductive material such as silver or copper may be filled in each of the through holes to form a respective conductive via that passes through the mold cap 110. The through holes or the vias can be aligned with the respective conductive pads or other similar structures on the interposers 101, such that conductive vias can be electrically coupled to the two interposers 101. In the embodiment shown in FIG. 1C, each of the two interposers 101 is electrically coupled with two conductive vias (i.e., one set of interconnects 121) for further connection of additional electronic modules thereon. In some other embodiments, each set of the two sets of interconnects 121 may include more than two conductive vias depending on actual layouts of the electronic device. In some embodiments, a planarization process such as a mechanical polishing or chemical mechanical polishing process may be implemented to achieve flat top surfaces of the conductive vias for uniform mounting of additional electronic modules thereon subsequently.

Next, as shown in FIG. 1D, two semiconductor dice 131 are mounted on the mold cap 110 and the electronic component 102. In some embodiments, the two semiconductor dice 131 may have the same height, and thus their top surfaces may be flush with each other. In some other embodiments, the top surfaces of the semiconductor dice 131 may not be flush with each other. Each of the two semiconductor dice 131 is electrically coupled to one of the two interposers 101 via one set of the two sets of interconnects 121. As such, the two semiconductor dice 131 and the electronic component 102 can be electronically connected via the two sets of interconnects 121 and the two interposers 101. Moreover, the two semiconductor dice 131 and the electronic component 102 can also be electrically coupled to the interconnect wires within the package substrate 100, thereby forming an integrated circuit device. The two interposers 101 electrically coupling the two semiconductor dice 131 with the electronic component 102 are flexible in design and can be disposed at any positions on the package substrate 100 according to a layout of the electronic device. In some embodiments, each of the two semiconductor dice 131 may include a memory die, for example, a high bandwidth memory die. In some other embodiments, each of the two semiconductor dice 131 may include a logic die. It can be appreciated that more semiconductor dice 131 may be mounted on the mold cap 110 and the electronic component 102. For example, one or more semiconductor dice 131 may be mounted on the mold cap 110 and optionally on the electronic component 102, and be electrically coupled to the package substrate 102 through one of the interposers 101.

In this embodiment, the two semiconductor dice 131 are arranged around the electronic component 102 and each of the two semiconductor dice 131 overlaps with a portion of the electronic component 102. In this way, a gap is formed between the two semiconductor dice 131 and exposes the front surface of the electronic component 102. The size of the gap may be determined according to the size of the two semiconductor dice 131, the size of the electronic component 102 as well as a total working area designed for the electronic device. The overlapping area between the two semiconductor dice 131 and the electronic component 102 contributes to a reduced size and an improved integration level of the electronic device compared with conventional 2.5D electronic package where the electronic component and the semiconductor dice are mounted side by side on the interposer. In other words, a larger overlapping area between the two semiconductor dice 131 and the electronic component 102 allows for a reduced package size of the electronic device. In some embodiments, the two semiconductor dice 131 are mounted onto front surfaces of the two sets of interconnects 121 via solder bumps or other conductive structures. Next, an underfill 130 is formed between bottom surfaces of the two semiconductor dice 131 and top surfaces of the mold cap 110 and the electronic component 102, so as to bond the semiconductor dice 131, the mold cap 110 and the electronic component 102 together.

In some other embodiments, two additional semiconductor dice may further be mounted onto the two semiconductor dice 131, where each of the two additional semiconductor dice may overlap with a portion of one respective semiconductor die 131 underneath the additional semiconductor die. Each of the two additional semiconductor dice may also be electrically coupled to one of the two interposers 101 via one additional set of interconnects. In this way, an integration level of the electronic device may further be improved.

It can also be appreciated that at least one additional interposer may further be disposed on the package substrate 100. Moreover, at least one additional set of interconnects may be mounted on the at least one additional interposer. At least one extra semiconductor die may be attached on the at least one additional set of interconnects to be electrically coupled to the at least one interposer, and the at least one extra semiconductor die may be disposed at the same level as the two semiconductor dice 131. In other words, more interposers, sets of interconnects and semiconductor dice may be mounted onto the package substrate 100 similarly as the interposers 101, sets of interconnects 121 and semiconductor dice 131 shown in FIG. 1D.

Next, as shown in FIG. 1E, a thermal interface material 140 is formed on top surfaces of the two semiconductor dice 131 and a top surface of a portion of the electronic component 102. The thermal interface material 140 may include a thermal paste, a thermal adhesive (e.g., metal oxide, carbon black, carbon nanotube), a phase-change material or a metal thermal interface material (e.g., indium alloy and sintered silver). The thermal interface material 140 may improve heat transfer from the electronic component 102 and the two semiconductor dice 131 to functional modules attached thereon.

Next, a heat spreader 160 is attached onto the two semiconductor dice 131 and the electronic component 102. To be more specific, the heat spreader 160 includes a base portion 160b attached onto the two semiconductor dice 131 via the thermal interface material 140 and a head portion 160a extending downward from the base portion 160b into the gap (defined by space between the two semiconductor dice 131) to be attached on the electronic component 102 via the thermal interface material 140. As such, both of the semiconductor dice 131 and the electronic component 102 can be thermally coupled to the heat spreader 160. In this way, both of the semiconductor dice 131 and the electronic component 102 are in direct contact with the heat spreader 160 via the thermal interface material 140 to allow for a more efficient heat transfer. In this way, heat energy generated from both of the semiconductor dice 131 and the electronic component 102 can be dissipated out of the electronic device through the heat spreader 160 and the thermal interface material 140 despite of a height difference between the electronic component 102 and the semiconductor dice 131. Therefore, the electronic device 170 with a reduced size and an improved heat dissipation capability is formed.

In some other embodiments, the electronic component 102 (for example, a system on a chip (SOC) module, a central processing (CPU) module or a graphics processing (GPU) module) may generate more heat compared with the semiconductor dice 131. In the embodiment shown in FIG. 1E, the heat spreader 160 has a uniform structure and a same material in both of the base portion 160b and the head portion 160a. The head portion 160a and the base portion 160b may be formed together as the heat spreader 160 as a single piece. The integrated heat spreader 160 may be pre-formed to mate with the shape of the semiconductor dice 131 and the electronic component 102. In some other embodiments, the head portion 160a may have a different structure from the base portion 160b to compensate for the difference in heat energy generated by the semiconductor dice 131 and the electronic component 102. For example, the head portion 160a may be structurally constructed to have a higher heat dissipation efficiency than that of the base portion 160b to dissipate more heat out of the electronic component 102 in a certain period of time. In some other embodiments, the head portion 160a and the base portion 160b may include different materials. For example, a material of the head portion 160a may have a larger heat transfer coefficient compared with that of a material of the base portion 160b. In this case, the head portion 160a may first be formed on the electronic component 102, and then the base portion 160b may be formed on the two semiconductor dice 131 and the head portion 160a.

Moreover, as shown in FIG. 1E, a size of the head portion 160a may be smaller than the gap between the two semiconductor dice 131, thereby leaving two openings or channels 150 each arranged between a lateral surface of the head portion 160a and a lateral surface of one of the two semiconductor dice 131. The openings 150 may provide room for expansion of the heat spreader 160 when heat is generated, thereby avoiding damages of the electronic device due to thermal expansion. It can also be appreciated that a flexible film may be formed between each of the two semiconductor dice 131 and the head portion 160a, which provides a buffer for expansion of the heat spreader 160. In some other embodiments, a size of the head portion 160a may be the same as the gap between the two semiconductor dice 131.

In some embodiments, the electronic device can be applied in packages which desire a reduced size and an improved heat dissipation capability, especially for highly integrated packages incorporating high-performance modules such as a system on a chip (SOC) module, a central processing (CPU) module, a graphics processing (GPU) module or a high bandwidth memory (HBM), which may have high power consumption and generate extensive heat when it is in operation.

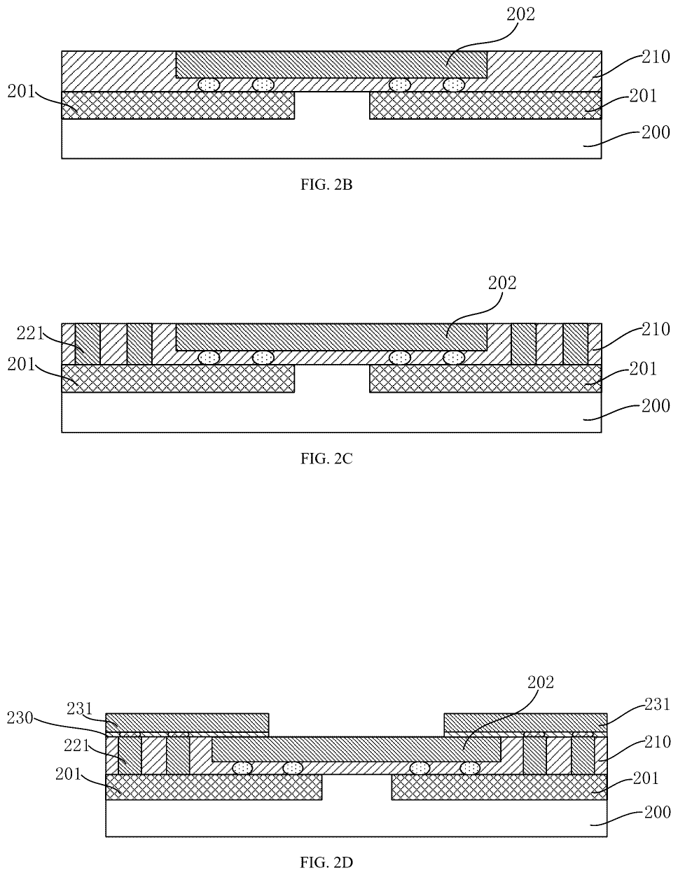

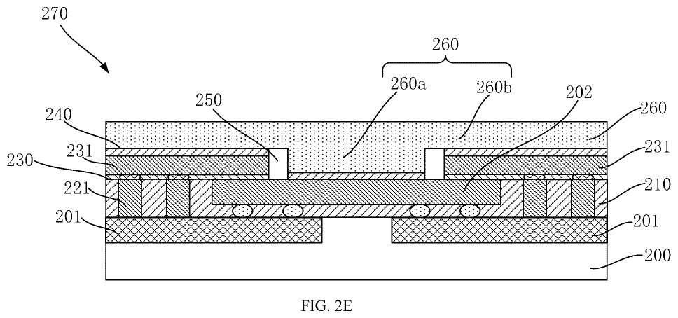

FIGS. 2A to 2E illustrate an electronic device and various steps of a method for forming the electronic device according to a second embodiment of the present application. The electronic device formed using the method may be shown in FIG. 2E.

As shown in FIG. 2A, a package substrate 200 is provided with embedded interconnect wires. Next, two cavities are formed within the package substrate 200 by removing a portion of the package substrate 200 using laser ablation, or other techniques such as etching, milling, drilling, pinching or their combinations. Next, two interposers 201 are disposed within the two cavities, respectively, which are electrically coupled to the package substrate 200. Front surfaces of the two interposers 201 and a front surface of the package substrate 200 are flush with one other for uniform mounting of additional modules thereon. The two interposers 201 embedded within the cavities of the package substrate 200 can utilize the thickness of the package substrate 200, and thus further contribute to a reduced height and an improved integration level of the electronic device.

Next, as shown in FIG. 2B, an electronic component 202 is mounted on the two interposers 201 via solder bumps. To be more specific, the electronic component 202 is mounted on at least a portion of a front surface of each of the two interposers 201 and across the gap between the two interposers 201. Next, a mold cap 210 is formed on a front surface of the package substrate 200 and front surfaces of the two interposers 201, so as to encapsulate the two interposers 201 and the electronic component 202 but expose a front surface of the electronic component 202.

Next, as shown in FIG. 2C, two sets of interconnects 221 are formed through the mold cap 210 to electrically couple each set of the two sets of interconnects 221 to one of the two interposers 201. In this embodiment, each set of the two sets of interconnects 221 may include two conductive vias being mounted on one of the two interposers 201. In some other embodiments, each set of the two sets of interconnects 221 may include one conductive via or more than two conductive vias depending on actual layouts of the electronic device.

Next, as shown in FIG. 2D, two semiconductor dice 231 are mounted on the mold cap 210 and the electronic component 202 via an underfill 230 to form a gap between the two semiconductor dice 231 and above the electronic component 202, and each of the two semiconductor dice 231 is electrically coupled to one of the two interposers 201 via one set of the two sets of interconnects 221. As such, the two semiconductor dice 231 and the electronic component 202 can be electronically connected via the two sets of interconnects 221 and the two interposers 201. Moreover, the two semiconductor dice 231 and the electronic component 202 can also be electrically coupled to the interconnect wires within the package substrate 200, thereby forming an integrated circuit device.

Next, as shown in FIG. 2E, a thermal interface material 240 is formed on top surfaces of the two semiconductor dice 231 and a top surface of the electronic component 202. Next, a heat spreader 260 is attached onto the two semiconductor dice 231 and the electronic component 202. To be more specific, the heat spreader 260 includes a base portion 260b attached onto the two semiconductor dice 231 via the thermal interface material 240 and a head portion 260a extending downward from the base portion 260b into the gap to be attached on the electronic component 202 via the thermal interface material 240. As such, both of the semiconductor dice 231 and the electronic component 202 can be thermally coupled to the heat spreader 260 to achieve an improved heat dissipation efficiency. In this way, an electronic device 270 with a reduced size and an improved heat dissipation capability is formed.

In some other embodiments, two additional semiconductor dice may further be mounted onto the two semiconductor dice 231, respectively, where each of the two additional semiconductor dice may overlap with a portion of one respective semiconductor die 231 underneath the additional semiconductor die. Each of the additional semiconductor dice may also be electrically coupled to one of the two interposers 201 via one additional set of interconnects.

The details of the formation process and the structures of the electronic device may be similar to those illustrated in the formation process and the structures of the electronic device shown in FIGS. 1A to 1E, which will not be elaborated in detail here for simplicity.

While the exemplary method for forming an electronic device of the present application is described in conjunction with corresponding figures, it will be understood by those skilled in the art that modifications and adaptations to the method for forming an electronic device may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. An electronic device, comprising:
a package substrate;
two interposers disposed on the package substrate;
an electronic component mounted on the two interposers to be electrically coupled to the package substrate via the two interposers;
a mold cap formed on the package substrate to encapsulate the two interposers and expose the electronic component, wherein the mold cap comprises two sets of interconnects extending therethrough and each being electrically coupled to one of the two interposers;
two semiconductor dice mounted on the mold cap and the electronic component to form a gap between the two semiconductor dice and above the electronic component, wherein each of the two semiconductor dice is electrically coupled to one of the two interposers via one set of the two sets of interconnects; and
a heat spreader attached on and thermally coupled to the two semiconductor dice, wherein a portion of the heat spreader extends downward into the gap to be thermally coupled to the electronic component.

2. The electronic device of claim 1, wherein the two interposers are juxtaposed on the package substrate and have top surfaces that are flush with each other to support the electronic component thereon.

3. The electronic device of claim 2, wherein the package substrate comprises two cavities each receiving one of the two interposers.

4. The electronic device of claim 2, wherein the mold cap comprises a protrusion extending downward onto the package substrate and between the two interposers.

5. The electronic device of claim 1, wherein the electronic component comprises a system on a chip (SOC) device.

6. The electronic device of claim 1, wherein each of the two semiconductor dice comprises a memory die.

7. The electronic device of claim 1, wherein each set of the two sets of interconnects comprise at least one conductive via.

8. The electronic device of claim 1, each of the two semiconductor dice overlaps with a portion of the electronic component.

9. A method for forming an electronic device, comprising:
providing a package substrate;
disposing two interposers on the package substrate;
mounting an electronic component on the two interposers;
forming a mold cap on the package substrate to encapsulate the two interposers and expose the electronic component;
forming two sets of interconnects through the mold cap to electrically couple each set of the two sets of interconnects to one of the two interposers;
mounting two semiconductor dice on the mold cap and the electronic component to form a gap between the two semiconductor dice and above the electronic component, wherein each of the two semiconductor dice is electrically coupled to one of the two interposers via one set of the two sets of interconnects; and
attaching a heat spreader on the two semiconductor dice to thermally couple the heat spreader to the two semiconductor dice, wherein a portion of the heat spreader extends downward into the gap to be thermally coupled to the electronic component.

10. The method of claim 9, wherein disposing two interposers on the package substrate comprises: juxtaposing the two interposers on the package substrate such that top surfaces of the two interposers are flush with each other.

11. The method of claim 10, wherein before disposing two interposers on the package substrate, the method further comprises: forming two cavities within the package substrate each for receiving one of the two interposers.

12. The method of claim 10, wherein forming a mold cap on the package substrate further comprises: forming the mold cap with a protrusion extending downward onto the package substrate and between the two interposers.

13. The method of claim 9, wherein each set of the two sets of interconnects comprise at least one conductive via, and forming two sets of interconnects through the mold cap comprises:
etching the mold cap to form two sets of through holes within the mold cap such that each set of the two sets of through holes comprise at least one through hole and expose a top surface of one of the two interposers; and
filling in the two sets of through holes a conductive material to form conductive vias through the mold cap.

14. The method of claim 9, wherein the electronic component comprises a system on a chip (SOC) device.

15. The method of claim 9, wherein each of the two semiconductor dice comprises a memory die.
